(19) United States
(12) Patent Application Publication
(10) Pub. No.: US 2003/0211418 A1
(43) Pub. Date: Nov. 13, 2003

(54) Photosensitive lithographic printing plate

(75) Inventor: Ikuo Kawauchi, Shizuoka (JP)

Correspondence Address: SUGHRUE MION, PLLC, 2100 PENNSYLVANIA AVENUE, N.W., WASHINGTON, DC, 20037, US

(73) Assignee: FUJI PHOTO FILM CO., LTD.

(21) Appl. No.: 10/419,736

(22) Filed: Apr. 22, 2003

(30) Foreign Application Priority Data
Apr. 22, 2002 (JP) P. 2002-119260

(51) Int. Cl. G03F 7/039

(52) U.S. Cl. 430/270.1; 430/286.1

(57) ABSTRACT

A photosensitive lithographic printing plate which comprises a photosensitive layer comprising: (A) a resin prepared by condensing substituted phenols represented by the following formula (I) with aldehydes; (B) a resin prepared by condensing phenols selected from cresol, phenol and xylenol with aldehydes; and (C) a light-heat converting substance:

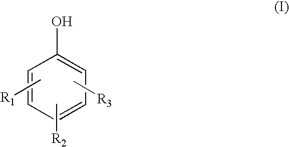

wherein R₁ and R₂ each represents a hydrogen atom, an alkyl group or a halogen atom, and R₃ represents an alkyl group having from 3 to 6 carbon atoms or cycloalkyl group having from 3 to 6 carbon atoms.

### FIELD OF THE INVENTION

This invention relates to photosensitive lithographic printing plates, particularly to a positive type photosensitive lithographic printing plate for so-called direct preparation use which can be prepared directly from digital signals of a computer and the like.

### BACKGROUND OF THE INVENTION

As the conventional system for directly preparing a plate from digital date of a computer, (1) an electrophotography, (2) a photo-polymerization system by a combination of exposure by Ar laser with after-heating, (3) a laminate of a silver salt sensitive material on a photosensitive resin, (4) a silver master type, (5) destruction of a silicone rubber layer by discharge breakdown or laser beam and the like are known.

However, the system which uses the electrophotography of (1) requires complex charge, exposure, development and the like treatment and the apparatus therefore becomes complex and large in scale. The method of (2) requires an after-heating step and also requires a high sensitivity plate material so that handling in a light room becomes difficult. The methods of (3) and (4) have an disadvantage in that the cost becomes high due to complex handling for using silver salts. Also, though the method of (5) is a method having relatively high completeness, it still has a problem in removing silicone residue remained on the plate surface.

On the other hand, development of lasers in recent years is remarkable, and particularly, high output and small size solid laser and semiconductor laser having a light generation range of from near infrared to infrared can now be obtained easily. These lasers are markedly useful as the exposure light source in directly preparing a plate from digital data of a computer and the like, in view of the miniaturization of plate preparation system, the environmental light at the time of plate preparation working, the plate preparation cost and the like.

As a conventional lithographic printing plate material, JP-B-46-27919 describes a method in which images are formed in accordance with the information by heating a recording material containing a polymer compound or composition which is insoluble or slightly soluble before heating but can become soluble in a solvent under influence of heat. Also, JP-A-56-69192 discloses a thermosensible recording material having a thermosensible layer containing a novolak type phenol resin and carbon black. However, these documents disclose only examples of a case when images were recorded without using laser beam, and when images were recorded using the aforementioned lasers having a light generation range of from near infrared to infrared as the exposure light source in directly preparing a plate from digital data of a computer and the like, it was not always able to obtain good printed matter due to greasing, reduced printing resistance and the like. In order to obtain good printed matter, it is necessary in carrying out alkali development treatment after exposure that light-irradiated parts (non-image parts) are easily dissolved, parts to which light is not applied (image parts) are remained and the remained image parts have good durability. That is, it is considered that the non-image parts are hardly dissolved and the image parts are apt to be dissolved when laser beams are used in the aforementioned known techniques due to poor image-recording ability.

However, improvements are still in demand for the photosensitive lithographic printing plates developed by the techniques disclosed in the above in terms of their ink acceptability (image density) and processing ability when activity of the developing solution is changed (development latitude).

### SUMMARY OF THE INVENTION

The object of the invention is to overcome the aforementioned disadvantages involved in the prior art techniques and thereby provide a photosensitive lithographic printing plate which is excellent in the ink acceptability (image density) and the processing ability (development latitude) in fatigued developing solution having decreased activity.

The aforementioned problems of the invention were solved by the following means.

(1) A photosensitive lithographic printing plate characterized in that it has a photosensitive layer (also to be referred to as image forming layer hereinafter) which contains

(A) a resin prepared by condensing substituted phenols represented by the following formula (I) with aldehydes

(B) a resin prepared by condensing phenols selected from cresol, phenol and xylenol with aldehydes, and

(C) a light-heat (photothermal) converting substance.

Formula (I):

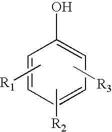

In the formula (I), R₁ and R₂ respectively represent hydrogen atom, an alkyl group-or a halogen atom, and R₃ represents an alkyl group or cycloalkyl group having from 3 to 6 carbon atoms.

### DETAILED DESCRIPTION OF THE INVENTION

The photosensitive lithographic printing plate of the invention is described in detail in the following.

The photosensitive lithographic printing plate of the invention is characterized in that it has a photosensitive layer which contains (A) a resin prepared by condensing substituted phenols represented by the following formula (I) with aldehydes, (B) a resin prepared by condensing phenols selected from cresol, phenol and xylenol with aldehydes, and (C) a light-heat converting substance.

Firstly, (A) the resin prepared by condensing substituted phenols represented by the formula (I) with aldehydes (to be referred sometimes to as resin (A) or component (A) hereinafter) is described in detail.

Formula (I):

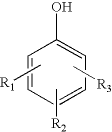

In the formula (I), R₁ and R₂ respectively represent hydrogen atom, an alkyl group or a halogen atom. The alkyl group is preferably an alkyl group having from 1 to 3 carbon atoms, more preferably an alkyl group having 1 or 2 carbon atoms. The halogen atom is any one of fluorine, chlorine, bromine and iodine, preferably chlorine or bromine. Also, R₃ represents an alkyl group or cycloalkyl group having from 3 to 6 carbon atoms.

Illustrative examples of the substituted phenols represented by the formula (I) to be used as a component of the resin (A) include isopropylphenol, tert-butylphenol, tert-amylphenol, hexylphenol, cyclohexylphenol, 3-methyl-4-chloro-6-tert-butylphenol, isopropylcresol, tert-butylcresol and tert-amylcresol. Preferred are tert-butylphenol and tert-butylcresol.

Examples of the aldehydes to be used in the resin (A) include aliphatic and aromatic aldehydes such as formaldehyde, acetaldehyde, acrolein, crotonaldehyde. Preferred is formaldehyde or acetaldehyde.

Weight average molecular weight of the resin (A) is preferably from 500 to 50,000, more preferably from 700 to 20,000, particularly preferably from 1,000 to 10,000.

Also, ratio of the resin (A) to the total solid components in the photosensitive layer of the photosensitive lithographic printing plate of the invention is preferably from 0.1% by weight to 20% by weight, more preferably from 0.2% by weight to 10% by weight, particularly preferably from 0.2% by weight to 5% by weight. The ratio of less than 0.1% by weight shows poor adding effect and exceeding 20% by weight reduces the sensitivity, so that both cases are not desirable.

Next, (B) the aforementioned resin prepared by condensing phenols selected from cresol, phenol and xylenol with aldehydes according to the invention (to be referred sometimes to as resin (B) or component(B) hereinafter) is described in detail.

Those which were described in relation to the resin (A) can be exemplified as the aldehydes to be used in the resin (B).

As the resin (B) to be used in the invention, a phenol-formaldehyde resin, an m-cresol-formaldehyde resin, a p-cresol-formaldehyde resin, m-/p-mixed cresol-formaldehyde resin, a phenol/cresol (either m-, p- or m-/p-mixture) mixed formaldehyde resin and the like novolak resins and pyrogallol-acetone resins can be desirably exemplified.

Also, its weight average molecular weight is preferably 500 or more, more preferably from 1,000 to 700,000. Also, its number average molecular weight is preferably 500 or more, more preferably from 750 to 650,000. It is desirable that its degree of dispersion (weight average molecular weight/number average molecular weight) is from 1.1 to 10.

In addition, amount of the resin (B) to be used in the invention in the photosensitive layer total solid components of the photosensitive lithographic printing plate is preferably from 10% by weight to 95% by weight, more preferably from 20% by weight to 90% by weight. When the content is less than 10% by weight, there is a case in which it cannot be used due to low print resistance improving effect by burning treatment.

It is desirable to further add a water-insoluble alkali water-soluble resin (to be referred to as alkali-soluble resin hereinafter) other than the resin (B) to the photosensitive lithographic printing plate of the invention.

Examples of the alkali-soluble resin include polyhydroxystyrene, polyhydroxystyrene halide, N-(4-hydroxyphenyl) methacrylamide copolymer and hydroquinone monomethacrylate copolymer, as well as the sulfonylimide polymers describe in JP-A-7-28244, the carboxyl group-containing polymers described in JP-A-7-36184 and the like. In addition, the phenolic hydroxyl group-containing acrylic resins disclosed in JP-A-51-34711, the sulfonamide group-containing acrylic resins describe in JP-A-2-866, urethane resins and the like various alkali-soluble polymer compounds can also be used. It is desirable that these alkali-soluble polymer compounds have a weight average molecular weight of from 500 to 200,000 and a number average molecular weight of from 200 to 60,000. Such alkali-soluble polymer compounds may be used alone or as a combination of two or more, and are used at an adding amount of 80% by weight or less based on the total composition.

The light-heat converting substance (C) to be used in the invention is not particularly limited, with the proviso that it is a substance which generates heat by absorbing infrared light, and not only infrared ray absorbing dyestuffs but also various pigments known as infrared ray absorbing pigments or infrared ray absorbing dyestuffs other than the exemplified ones can be used.

As the pigments, commercially available pigments and pigments described in Color Index (C. I.) Handbook, “Recent Pigment Handbook” (edited by Japan Association of Pigment Techniques, published in 1977), “Recent Pigment Application Techniques” (CMC Publication, published in 1986) and “Printing Ink Techniques” (CMC Publication, published in 1984) can be used.

Types of the pigment include a black pigment, a yellow pigment, an orange pigment, a brown pigment, a red pigment, a purple pigment, a blue pigment, a green pigment, a fluorescence pigment and a metal powder pigment, as well as a polymer-bonded pigment. Illustratively, an insoluble azo pigment, an azo lake pigment, a condensed azo pigment, a chelate azo pigment, a phthalocyanine pigment, an anthraquinone pigment, a perylene or perynone pigment, a thioindigo pigment, a quinacridone pigment, a dioxazine pigment, an isoindolinone pigment, a quinophthalone pigment, a dyed lake pigment, an azine pigment, a nitroso pigment, a nitro pigment, a natural pigment, a fluorescence pigment, an inorganic pigment, carbon black and the like can be used.

These pigments may be used without carrying out a surface treatment or by applying a surface treatment. Examples of the surface-treating method include a method in which a resin or wax is surface-coated, a method in which a surface active agent is adhered and a method in which a reactive substance (e.g., a silane coupling agent, an epoxy compound, a polyisocyanate or the like) is linked to the pigment surface. These surface-treating methods are described in “Properties and Application of Metal Soap” (Saiwai Shobo), “Printing Ink Techniques” (CMC Publication, published in 1984) and “Recent Pigment Application Techniques” (CMC Publication, published in 1986).

Particle diameter of pigment is preferably within the range of from 0.01 μm to 10 μm, more preferably within the range of from 0.05 μm to 1 μm, particularly preferably within the range of from 0.1 μm to 1 μm. A pigment particle diameter of less than 0.01 μm is not desirable in terms of the stability of its dispersion in a recording layer coating solution, exceeding 10 μm is not desirable in terms of the uniformity of the recording layer.

As the method for dispersing pigment, known dispersing techniques used in ink production, toner production and the like can be used. Examples of the dispersing machine include ultrasonic dispersion equipment, sand mill, atomizer, pearl mill, super mill, ball mill, impeller, disperser, KD mill, colloid mill, dynatron, three roll mill, compression kneader and the like. Details are described in “Recent Pigment Application Techniques” (CMC Publication, published in 1986).

As the dyestuff, commercially available dyestuffs and known compounds described in references (e.g., “Dyestuff Handbook” edited by the Society of Organic Synthesis Chemistry, published in 1970) can be used. Illustratively, an azo dye, a metal complex azo due, a pyrazolone azo dye, an anthraquinone dye, a phthalocyanine dye, a carbonium dye, a quinone imine dye, a methine dye, a cyanine dye and the like dyestuffs can be exemplified.

According to the invention, among these pigments or dyestuffs, those which absorb infrared light or near infrared light are particularly desirable in terms that they are suited for the use of a laser which emits infrared light or near infrared light.

As such pigment which absorbs infrared light or near infrared light, carbon black is suitably used. Also, examples of the dyestuff which absorbs infrared light or near infrared light include cyanine dyestuffs described in JP-A-58-125246, JP-A-59-84356, JP-A-59-202829, JP-A-60-78787 and the like, methine dye stuffs described in JP-A-58-173696, JP-A-58-181690, JP-A-58-194595 and the like, naphthoquinone dyestuffs described in JP-A-58-112793, JP-A-58-224793, JP-A-59-48187, JP-A-59-73996, JP-A-60-52940, JP-A-60-63744 and the like, squalilium pigments described in JP-A-58-112792 and the like, and cyanine dyestuffs described in British Patent 434,875.

In addition, as dyestuffs, the near infrared absorption sensitizer described in U.S. Pat. No. 5,156,938 can also be used suitably, and the substituted arylbenzo(thio)pyrylium salts described in U.S. Pat. No. 3,881,924, trimethinethiapyrylium salts described in JP-A-57-142645 (U.S. Pat. No. 4,327,169), pyrylium compounds described in JP-A-58-181051, JP-A-58-220143, JP-A-59-41363, JP-A-59-84248, JP-A-59-84249, JP-A-59-146063 and JP-A-59-146061, cyanine pigments described in JP-A-59-216146, pentamethinethiopyrylium salts and the like described in U.S. Pat. No. 4,283,475, pyrylium compounds and the like described in JP-B-5-13514 and JP-B-5-19702 and, as commercial products, Epolight III-178, Epolight III-130, Epolight III-125 and the like manufactured by Epolin, are particularly preferably used.

In addition, the near infrared absorbing dyestuffs described as formulae (I) and (II) in the specification of U.S. Pat. No. 4,756,993 can be cited as another examples of particularly preferred dyestuffs.

These pigments or dyestuffs can be added at a ratio of from 0.01 to 50% by weight, preferably from 0.1 to 10% by weight, and particularly preferably from 0.5 to 10% by weight in the case of dyestuffs or particularly preferably from 3.1 to 10% by weight in the case of pigments, based on the total solid components.

The sensitivity becomes low when the adding amount of pigments or dyestuffs is less than 0.01% by weight, and when it exceeds 50% by weight, uniformity of the image forming layer is lost and durability of the image forming layer becomes poor. These dyestuffs or pigments may be added to the same layer of other components or added to a separately arranged layer.

Next, other components which can be added in case of preparing a photosensitive composition for image forming layer use, according to the photosensitive lithographic printing plate of the invention, are described.

As occasion demands, cyclic acid anhydrides, phenols and organic acids can be added to the photosensitive composition in order to improve sensitivity. In addition, a printing out agent for obtaining visible images immediately after exposure, a dyestuff as an image coloring agent, other fillers and the like can also be added.

Examples of the cyclic acid anhydride include phthalic anhydride, tetrahydrophthalic anhydride, hexahydrophthalic anhydride, 3,6-endoxy-Δ4-tetrahydrophthalic anhydride, tetrachlorophthalic anhydride, maleic anhydride, chloromaleic anhydride, α-phenylmaleic anhydride, succinic anhydride, pyromellitic anhydride and the like, as described in the specification of U.S. Pat. No. 4,115,128. As the phenols, bisphenol A, p-nitrophenol, p-ethoxyphenol, 2,3,4-trihydroxybenzophenone, 4-hydroxybenzophenone, 2,4,4′-trihydroxybenzophenone, 4,4′,4″-trihydroxy-triphenylmethane, 4,4′,3″,4″-tetrahydroxy-3,5,3′,5′-tetramethyltriphenylmeth ane and the like can be exemplified.

Examples of the organic acids include sulfonic acids, sulfinic acids, alkyl sulfates, phosphonic acids, phosphinic acids, phosphoric acid esters, carboxylic acids and the like described in JP-A-60-88942, JP-A-2-96755 and the like, and their illustrative examples include p-toluenesulfonic acid, dodecylbenzenesulfonic acid, p-toluenesulfinic acid, ethyl sulfate, phenylphosphonic acid, phenylphosphinic acid, phenyl phosphate, diphenyl phosphate, benzoic acid, isophthalic acid, adipic acid, p-toluic acid, 3,4-dimethoxybenzoic acid, phthalic acid, terephthalic acid, 1,4-cyclohexene-2,2-dicarboxylic acid, erucic acid, lauric acid, n-undecanoic acid, ascorbic acid and the like.

Ratio of the above cyclic acid anhydrides, phenols and organic acids occupying the photosensitive composition is preferably from 0.05 to 15% by weight, more preferably from 0.1 to 5% by weight.

As the printing out agent for obtaining visible images immediately after exposure, a combination of a photosensitive compound which releases an acid by exposure and an organic dyestuff that changes color tone by forming a salt with the acid can be exemplified.

Examples of the photosensitive compound which releases an acid by exposure include o-naphthoquinone diazide-4-sulfonic acidhalogenide described in JP-A-50-36209; trihalomethyl-2-pyrone and trihalomethyl-s-triazine described in JP-A-53-36223; various o-naphthoquinone diazide compounds described in JP-A-55-62444; 2-trihalomethyl-5-aryl-1,3,4-oxadiazole compounds described in JP-A-55-77742; diazonium salts and the like.

These compounds can be used alone or as a mixture, and their adding amount is preferably within the range of from 0.3 to 15% by weight based on the total weight of the composition.

At least one or more of organic dyestuffs which change color tone by mutually reacting with a photo-disintegration product of a compound that generates an acidic substance by photo-disintegration are used in the composition for photosensitive layer use of the photosensitive lithographic printing plate of the invention.

As such organic dyestuffs, pigments of diphenylmethane system, triarylmethane system, thiazine system, oxazine system, phenazine system, xanthene system, anthraquinone system, iminonaphthoquinone system and azomethine system can be used. Their illustrative examples are as follows.

Brilliant Green, Eosine, Ethyl Violet, Erythrocin B, Methyl Green, Crystal Violet, Basic Fuchsine, phenolphthalein, 1,3-diphenyltriazine, Alizarin Red S, Thymolphthalein, Methyl Violet 2B, Quinaldine Red, Rose Bengale, Thymolsulfophthalein, Xylenol Blue, Methyl Orange, Orange IV, diphenylthiocarbazone, 2,7-dichlorofluorescein, p-Methyl Red, Congo Red, Benzopurpurine 4B, α-Naphthyl Red, Nile Blue 2B, Nile Blue A, phenacetalin, Methyl Violet, Malachite Green, p-Fuchsine, Oil Blue #603 (mfd. by Orient Chemical Industry), Oil Pink #312 (mfd. by Orient Chemical Industry), Oil Red 5B (mfd. by Orient Chemical Industry), Oil Scarlet #308 (mfd. by Orient Chemical Industry), Oil Red OG (mfd. by Orient Chemical Industry), Oil Red RR (mfd. by Orient Chemical Industry), Oil Green #502 (mfd. by Orient Chemical Industry), Spiron Red BEH Special (mfd. by Hodogaya Chemical Industry), Victoria Pure Blue BOH (mfd. by Hodogaya Chemical Industry),

Patent Pure Blue (mfd. by Sumitomo Mikuni Chemical Industry), SudanBlue II (mfd. by BASP), m-cresolpurple, Cresol Red, Rhodamine B, Rhodamine 6G, Fast Acid Violet R, Sulfo Rhodamine B, auramine, 4-p-diethylaminophenyliminonaphthoquinone, 2-carboxyanilino-4-p-dihydroxyethyl-amino-phenyliminonapht hoquinone, p-methoxybenzoyl-p′-diethylamino-o′-methylphenyliminoaceta nilide, cyano-p-diethylaminophenyliminoacetanilide, 1-phenyl-3-methyl-4-p-diethylaminophenylimino-5-pyrazolone, 1-β-naphthyl-4-p-diethylaminophenylimino-5-pyrazolone and the like.

Particularly preferable organic dyestuffs are triarylmethane system dyestuffs. Among triarylmethane system dyestuffs, those which have sulfonic acid compounds as counter ions as shown in JP-A-62-2932471 and Japanese Patent No. 2,969,021 are particularly useful.

These dyestuffs can be used alone or as a mixture, and their adding amount is preferably from 0.3 to 15% by weight based on the total weight of the composition for photosensitive layer use. In addition, they can be used jointly with other dyestuffs and pigments as occasion demands, and their using amount is preferably 70% by weight or less, more preferably 50% by weight or less, based on the total weight of the dyestuffs and pigments.

In addition to these, various additives can be added to the composition for photosensitive layer use in response to various objects, including various resins having hydrophobic groups for the purpose of improving ink density of images, such as octylphenol formaldehyde resins, t-butylphenol formaldehyde resins, t-butylphenol benzaldehyde resins, rosin-modified novolak resins, o-naphthoquinone diazide sulfonic acid esters of these modified novolak resins and the like; and plasticizers for the purpose of improving flexibility of coating films, such as dibutyl phthalate, dioctyl phthalate, butyl glycolate, tricresylphosphate, dioctyl adipate and the like. Their adding amount is preferably within the range of from 0.01 to 30% by weight based on the total composition weight.

In addition, known resins for further improving abrasion resistance of coating films can be added to these compositions. Examples of these resins include a polyvinyl acetal resin, a polyurethane resin, an epoxy resin, a vinyl chloride resin, nylon, a polyester resin, an acrylic resin and the like, which can be used alone or as a mixture. Their adding amount is preferably within the range of from 2 to 40% by weight based on the total composition weight.

In addition, nonionic surface active agents such as those described in JP-A-62-251740 and JP-A-4-68355 and ampholytic surface active agents such as those described in JP-A-59-121044 and JP-A-4-13149 can be added to said composition for the purpose of expanding the development latitude. Illustrative examples of the nonionic surface active agents include sorbitan tristearate, sorbitan monopalmitate, sorbitan trioleate, stearic acid monoglyceride, polyoxyethylene sorbitan monooleate, polyoxyethylene nonyl phenyl ether and the like, and illustrative examples of the ampholytic surface active agents include alkyl di(aminoethyl)glycine, alkyl polyaminoethylglycine hydrochloride, Amorgen K (trade name, mfd. by Daiichi Kogyo Pharmaceutical, N-tetradecyl-N,N-betaine type), 2-alkyl-N-carboxyethyl-N-hydroxyethylimidazoliumbetaine, Levon 15 (trade name, mfd. by Sanyo Kasei, alkylimidazoline system) and the like.

Ratio of the above nonionic surface active agents and ampholytic surface active agents occupying the composition for photosensitive layer use is preferably from 0.05 to 15% by weight, more preferably from 0.1 to 5% by weight.

Improvement of application surface quality; Surface active agents for improving application surface quality, such as the fluorine system surface active agents described in JP-A-62-170950, can be added to said composition for photosensitive layer use.

The adding amount is preferably from 0.001 to 1.0% by weight, more preferably from 0.005 to 0.5% by weight, based on the total composition.

In addition, a yellow dyestuff, preferably a yellow dyestuff whose absorbance at 417 nm is 70% or more of its absorbance at 436 nm, can be added to the composition for photosensitive layer use.

When a photosensitive material for lithographic printing plate use is obtained from a resin composition for photosensitive layer-use, it is firstly arranged as an image forming layer on an appropriate support. The resin composition for photosensitive layer use is dissolved or dispersed in a single or mixed organic solvents described below, coated on the support and then dried.

As the organic solvents, any one of conventionally known ones can be used, but those having a boiling point of within the range of from 4⁰° C. to 200° C., particularly from 60° C. to 160° C., are selected due to their advantageousness in carrying out drying.

Examples of the organic solvents include methyl alcohol, ethyl alcohol, n-or iso-propyl alcohol, n-or iso-butyl alcohol, diacetone alcohol and the like alcohols, acetone, methyl ethyl ketone, methyl propyl ketone, methyl butyl ketone, methyl amyl ketone, methyl hexyl ketone, diethyl ketone, diisobutyl ketone, cyclohexanone, methylcyclohexanone, acetylacetone and the like ketones, benzene, toluene, xylene, cyclohexane, methoxybenzene and the like hydrocarbons, ethyl acetate, n- or iso-propyl acetate, n- or iso-butyl acetate, ethylbutyl acetate, hexyl acetate and the like acetic acid esters, methylene dichloride, ethylene dichloride, monochlorobenzene and the like halides, isopropyl ether, n-butyl ether, dioxane, dimethyldioxane, tetrahydrofuran and the like ethers, ethylene glycol, methyl cellosolve, methyl cellosolve acetate, ethyl cellosolve, diethyl cellosolve, cellosolve acetate, butyl cellosolve, butyl cellosolve acetate, methoxymethoxyethanol, diethylene glycol monomethyl ether, diethylene glycol dimethyl ether, diethylene glycol methylethyl ether, diethylene glycol diethyl ether, propylene glycol, propylene glycol monomethyl ether, propylene glycol monomethyl ether acetate, propylene glycol monoethyl ether, propylene glycol monoethyl ether acetate, propylene glycol monobutyl ether, 3-methyl-3-methoxybutanol and the like polyhydric alcohols and derivatives thereof, and dimethyl sulfoxide, N,N-dimethylformamide and the like special solvents, which are suitably used alone or as a mixture. In addition, it is suitable to adjust solid matter in the composition to be coated to a concentration of from 2 to 50% by weight.

According to the photosensitive lithographic printing plate of the invention, examples of the method for coating the composition for photosensitive layer use include roll coating, dip coating, air knife coating, gravure coating, gravure offset coating, hopper coating, blade coating, wire doctor coating, spray coating and the like methods, and the coating amount is preferably from 0.3 to 4.0 g/m² as the weight after drying. As the coating amount is reduced, exposure quantity for obtaining images can be lessened but the film strength is reduced. As the coating amount is increased, more larger exposure quantity is required but the photosensitive film becomes strong; for example, when it is used as a printing plate, a printing plate having high printable numbers (high printing resistance) is obtained.

Drying of the composition for photosensitive layer use coated on the support is carried out generally with heated air. The heating is carried out within the range of preferably from 30° C. to 200° C., particularly from 40° C. to 140° C. The drying can be carried out by not only a method in which the temperature is maintained at a constant level during the drying but also by a method in which it is increased step by step. In addition, good results are obtained in some cases when the drying air is dehumidified. It is desirable that the heated air is supplied to the coated face at a rate of from 0.1 m/second to 30 m/second, particularly from 0.5 m/second to 20 m/second.

Mat layer; In order to shorten vacuuming time in carrying out contact exposure using a vacuum printing frame and also to prevent printing blur, it is desirable to arrange a mat layer on the surface of the photosensitive layer arranged in the above manner. Its illustrative examples include a method in which a mat layer is arranged as described in JP-A-50-125805, JP-B-57-6582 and JP-B-61-28986 and a method in which a solid powder is hot-melted as described in JP-B-62-62337.

The support to be used in the photosensitive lithographic printing plate is a dimensionally stable flat material, and those which have so far been used as supports of printing plates are included therein and can be used suitably. Examples of such supports include paper, paper laminated with plastics (e.g., polyethylene, polypropylene, polystyrene and the like), metal plates such as of aluminum (including aluminum alloy), zinc, iron, copper and the like, films of plastics such as cellulose triacetate, cellulose propionate, cellulose butyrate, cellulose butyrate acetate, cellulose nitrate, polyethylene terephthalate, polyethylene, polystyrene, polypropylene, polycarbonate, polyvinyl acetal and the like, and paper or plastic films on which the aforementioned metals are laminated or deposited, of which aluminum plates are desirable. Pure aluminum plate and aluminum alloy plate are included in the aluminum plates. Various compounds are used as the aluminum alloy, and alloys of aluminum with metals such as silicon, copper, manganese, magnesium, chrome, zinc, lead, bismuth, nickel and the like are used. These compositions contain impurities in negligible degree of amounts in addition to some iron and titanium.

The support is surface-treated as occasion demands. It is desirable to apply a hydrophilic treatment to the support surface of the photosensitive lithographic printing plate. Also, in the case of a support having surface of a metal, particularly aluminum, it is desirable to carry out a surface treatment such as pebbling treatment, soaking treatment in sodium silicate, potassium borozirconate, phosphate or the like aqueous solution, or anodic oxidation treatment. In addition, an aluminum plate prepared by carrying out pebbling and then soaking in sodium silicate aqueous solution as described in U.S. Pat. No. 2,714,066 and an aluminum plate prepared by carrying out an anodic oxidation treatment and then soaking in an alkali metal silicate aqueous solution as described in U.S. Pat. No. 3,181,461 can also be used suitably.

The aforementioned anodic oxidation treatment is carried out for example by electrifying, using an aluminum plate as the anode, in electrolytes of phosphate, chromic acid, sulfuric acid, boric acid and the like inorganic acids, oxalic acid, sulfamic acid and the like organic acids or aqueous solutions or non-aqueous solutions of salts thereof, alone or a combination of two or more thereof.

Also effective is an electrode position of silicate as described in U.S. Pat. No. 3,658,662. These hydrophilic treatments are carried out not only to make the support surface hydrophilic but also to prevent undesired reaction with the photosensitive composition arranged thereon and to improve adhesiveness with the photosensitive layer. Prior to carrying out pebbling of the aluminum plate, as occasion demands, a pretreatment of its surface may be carried out to remove rolling oil from the surface and to expose clear aluminum surface.

For the former case, trichlene or the like solvent, a surface active agent or the like is used. For the latter case, a method which uses sodium hydroxide, potassium hydroxide or the like alkali etching agent is broadly carried out.

As the pebbling method, any of mechanical, chemical and electrochemical methods is effective. The mechanical method includes a ball polishing, a blast polishing and a brush polishing in which a water dispersion slurry of a pumice or the like abrasive material is rubbed with a nylon brush, as the chemical method, a method for soaking in a saturated aqueous solution of a mineral acid aluminum salt as described in JP-A-54-31187 is suited, and as the electrochemical method, a method for carrying out alternating current electrolysis in acidic electrolytes such as of hydrochloric acid, nitric acid or a combination thereof is desirable. Among these surface roughening methods, a surface roughening method in which a mechanical surface roughening is combined with an electrochemical surface roughening as described in JP-A-55-137993 is particularly desirable because of high adhesive strength of lipid-sensitive images to the support. It is desirable to carry out the pebbling by the aforementioned method in such a manner that the center line surface roughness (Ra) of the aluminum plate surface becomes a range of from 0.3 to 1.0 μm. As occasion demands, the aluminum plate pebbled in this manner is washed with water and chemically etched.

The etching treatment solution is selected generally from aqueous solutions of bases or acids which dissolve aluminum. In this case, a coat different from the aluminum derived from the etching solution components should not be formed on the etched surface. Preferred examples of the etching agent include sodium hydroxide, potassium hydroxide, sodium tertiary phosphate, sodium secondary phosphate, potassium tertiary phosphate, potassium secondary phosphate and the like as basic substances; and sulfuric acid, persulfuric acid, phosphoric acid, hydrochloric acid, salts thereof and the like as acidic substances, but salts of metals having lower ionizing tendency than aluminum, such as zinc, chrome, cobalt, nickel, copper and the like, are not desirable because they form unnecessary coats on the etching surface. In employing the concentration and temperature of these etching agents, it is most desirable that the dissolution rate of the aluminum or alloy to be used becomes 0.3 g to 40 g/m² per 1 minute of the soaking time, but it may be larger than or smaller than this range.

The etching is carried out for example by soaking an aluminum plate in the aforementioned etching solution or applying the etching solution to said aluminum plate, and it is desirable to carry out the treatment such that the etching amount becomes within the range of from 0.5 to 10 g/m². As the aforementioned etching agent, it is desirable to use an aqueous solution of a base in view of its characteristic quick etching speed. Since smut is formed in this case, desmutting is generally carried out. As the acid to be used in the desmutting, nitric acid, sulfuric acid, phosphoric acid, chromic acid, hydrofluoric acid, borohydrofluoric acid or the like is used. As occasion demands, the etching-treated aluminum plate is washed with water and subjected to anodic oxidation. The anodic oxidation can be carried out by a method conventionally used in this field.

Illustratively, an anodic oxidation coat can be formed on the aluminum support surface when continuous or alternate current is applied to aluminum in an aqueous solution or non-aqueous solution of sulfuric acid, phosphoric acid, chromic acid, oxalic acid, sulfamic acid, benzenesulfonic acid or the like or a combination of two or more thereof.

The anodic oxidation treating conditions cannot be determined in general, because they change in various manners depending on the electrolytic solutions to be used, but they are generally within the ranges of from 1 to 80% by weight as the concentration of electrolytic solution, from 5 to 70° C. as the solution temperature, from 0.5 to 60 A/dm² as the current density, from 1 to 100 V as the voltage and from 30 seconds to 50 minutes as the electrolysis time. Preferred among these anodic oxidation treatments are a-method described in British Patent 1,412,768 in which anodic oxidation is carried out in sulfuric acid at a high current density and a method described in U.S. Pat. No. 3,511,661 in which anodic oxidation is carried out using phosphoric acid as the electrolytic bath. The aluminum plate subjected to surface roughening and subsequent anodic oxidation in the aforementioned manner may be further subjected to a hydrophilic treatment as occasion demands, and its preferred examples include those methods in which it is treated with aqueous solution of an alkali metal silicate such as sodium silicate as disclosed in U.S. Pat. Nos. 2,714,066 and 3,181,461, with potassium borozirconate as disclosed in JP-B-36-22063 and with polyvinyl phosphonate as disclosed in U.S. Pat. No. 4,153,461.

Organic undercoat layer; For the purpose of reducing residual photosensitive layer in the non-image parts, it is desirable to arrange an organic undercoat layer on the photosensitive lithographic printing plate of the invention before coating the photosensitive layer. The organic compound to be used in such an organic undercoat layer is selected, for example, from carboxymethylcellulose, dextrin, gum arabic, 2-aminoethylphosphonic acid and the like amino group-containing phosphonic acids, phenylphosphonic acid, naphthylphosphonic acid, alkylphosphonic acid, glycerophosphonic acid, methylenediphosphonic acid, ethylenediphosphonic acid and the like organic phosphonic acids which may have substituent groups, phenyl phosphate, naphthyl phosphate, alkyl phosphate, glycerophosphate and the like organic phosphoric acids which may have substituent groups, phenylphosphinic acid, naphthylphosphinic acid, alkylphosphinic acid, glycerophosphinic acid and the like organic phosphinic acids which may have substituent groups, glycine, β-alanine and the like amino acids and triethanolamine hydrochloride and the like amine hydrochlorides having hydroxyl group, which may be used as a mixture of two or more.

In addition, it is desirable to contain a compound having onium group in the organic undercoat layer. Compounds having onium group are described in detail in JP-A-2000-10292, JP-A-2000-108538 and the like.

In addition to the above, at least one compound selected from polymer compounds having a structural unit typified by poly(p-vinylbenzoic acid) or the like in the molecule can be used. Its illustrative examples include a copolymer of p-vinylbenzoic acid with vinylbenzyltriethylammonium salt and a copolymer of p-vinylbenzoic acid with vinylbenzyltrimethylammonium chloride.

This organic undercoat layer can be arranged by the following methods. That is, a method in which it is arranged by preparing a solution by dissolving the aforementioned organic compound in water or methanol, ethanol, methyl ethyl ketone or the like organic solvent or a mixed solvent thereof, and coating and drying it on an aluminum plate, and a method in which an aluminum plate is soaked in a solution prepared by dissolving the aforementioned organic compound in water or methanol, ethanol, methyl ethyl ketone or the like organic solvent or a mixed solvent thereof, thereby effecting adsorption of the aforementioned organic compound, and then the organic undercoat layer is arranged by washing the plate with water or the like and subsequent drying. In the former method, a solution of the aforementioned organic compound having a concentration of from 0.005 to 10% by weight can be coated by various methods. For example, any of bar coater coating, roll coating, spray coating curtain coating and the like may be used. Also, in the latter method, concentration of the solution is from 0.01 to 20% by weight, preferably from 0.05 to 5% by weight, the soaking temperature is from 20 to 90° C., preferably from 25 to 50° C., and the soaking period is from 0.1 second to 20 minutes, preferably from 2 seconds to 1 minute.

The solution to be used in this can be used within the range of from pH 1 to 12 by adjusting the pH with ammonia, triethylamine, potassium hydroxide or the like basic substance and hydrochloric acid, phosphoric acid or the like acidic substance. Also, a yellow dye can be added for the purpose of improving tone reproducibility of the photosensitive lithographic printing plate. In addition, a compound represented by the following formula (a) can also be added.

Formula (a):

(HO)ₓ—R₅—(COOH)_{y}

With the proviso that R₅ represents an arylene group having 14 or less carbon atoms which may have a substituent group, and x and y are each independently an integer of from 1 to 3. Illustrative examples of the compound represented by the above formula (a) include 3-hydroxybenzoic acid, 4-hydroxybenzoic acid, salicylic acid, 1-hydroxy-2-naphthoic acid, 2-hydroxy-1-naphthoic acid, 2-hydroxy-3-naphthoic acid, 2,4-dihydroxybenzoic acid, 10-hydroxy-9-anthracenecarboxylic acid and the like. Coating amount of the organic undercoat layer after drying is preferably from 1 to 100 mg/m², more preferably from 2 to 70 mg/m². Sufficient print resistance performance cannot be obtained when the coating amount is smaller than 1 mg/m². This is the same when it is larger than 100 mg/m^{2.}

Back coat; As occasion demands, a back coat is arranged on the backside of the support. Preferably used as such back coat are coat layers comprising metal oxides obtained by carrying out hydrolysis and condensation polymerization of the organic polymer compounds described in JP-A-5-45885 and the organic or inorganic metal compounds described in JP-A-6-35174. Regarding these coat layers, Si(OCH₃)₄, Si(OC₂H₅)₄, Si(OC₃H₇)₄, Si(OC₄H₉)₄ and the like alkoxy compounds of silicon are in expensive and easily available, and coat layers of metal oxides obtained therefrom are particularly desirable because of their excellent developing solution resistance.

The photosensitive lithographic printing plate prepared in the above manner is generally subjected to image exposure and developing treatment. As the light source of active light to be used in the image exposure, a light source having an emission wavelength within the range of from near infrared to infrared is desirable, and a solid laser or semiconductor laser is particularly desirable.

The developing solution which can be employed in the developing treatment of the photosensitive lithographic printing plate of the invention is a developing solution having a pH value of within the range of from 9.0 to 14.0, preferably within the range of from 12.0 to 13.5. A conventionally known alkali aqueous solution can be used in the developing solution (to be called developing solution including replenisher hereinafter). For example, sodium silicate, potassium silicate, sodium tertiary phosphate, potassium tertiary phosphate, ammonium tertiary phosphate, sodium secondary phosphate, potassium secondary phosphate, ammonium secondary phosphate, sodium carbonate, potassium carbonate, ammonium carbonate, sodiumbicarbonate, potassiumbicarbonate, ammonium bicarbonate, sodiumborate, potassiumborate, ammoniumborate, sodium hydroxide, ammonium hydroxide, potassium hydroxide, lithium hydroxide and the like inorganic alkali salts can be cited. Also included are monomethylamine, dimethylamine, trimethylamine, monoethylamine, diethylamine, triethylamine, monoisopropylamine, diisopropylamine, triisopropylamine, n-butylamine, monoethanolamine, diethanolamine, triethanolamine, monoisopropanolamine, diisopropanolamine, ethyleneimine, ethylenediamine, pyridine and the like organic alkali agents. These alkali aqueous solutions maybe used alone or as a mixture of two or more.

Among the aforementioned alkali aqueous solutions, one of the developing solutions which exert the effect of the invention is an aqueous solution of pH 12 or more, so-called “silicate developing solution”, containing an alkali silicate as the base or containing an alkali silicate prepared by mixing a base with a silicon compound, and the other more preferred developing solution is so-called “non-silicate developing solution” which does not contain an alkali silicate but contains a non-reducing sugar (an organic compound having buffer action) and a base.

In the former case, developing ability of the aqueous solution of alkali metal silicate can be controlled by the ratio of silicon oxide (SiO₂) as a component of the silicate to the alkalimetal oxide M₂O (generally expressed as [SiO₂]/[M₂O] molar ratio) and their concentrations, and its suitably useful examples include a sodium silicate aqueous solution disclosed in JP-A-54-62004 in which the SiO₂/Na₂O molar ratio is from 1.0 to 1.5 (namely, [SiO₂]/[Na₂O] is from 1.0 to 1.5) and the SiO₂ content is from 1 to 4% by mass and an alkali metal silicate aqueous solution disclosed in JP-B-57-7427 in which the [SiO₂]/[M] is from 0.5 to 0.75 (namely, [SiO₂]/[M₂O] is from 1.0 to 1.5) and the SiO₂ concentration is from 1 to 4% by mass, wherein said developing solution contains at least 20% of potassium based on the gram atoms of the total alkali metals existing therein.

In addition, the so-called “non-silicate developing solution” which does not contain alkali silicate but contains a non-reducing sugar and a base is also suitable for applying to the development of the lithographic printing plate material of the invention. When developing treatment of the lithographic printing plate material is carried out using this developing solution, deterioration of the surface of photosensitive layer does not occur and image density of the photosensitive layer can be maintained under more superior condition.

It is desirable that this developing solution comprises at least one compound selected from non-reducing sugars and at least one base as its main components and its liquid pH is within the range of from 9.0 to 13.5. Such non-reducing sugars are saccharides which do not have free aldehyde group and ketone group and do not show reducing property and are classified into trehalose type oligosaccharides in which reducing groups are mutually bonded, glycosides in which reducing groups of saccharides and non-saccharides are bonded and sugar alcohols prepared by reducing saccharides through hydrogenation, and all of them can be used suitably. The trehalose type oligosaccharides include sucrose and trehalose, and examples of the glycosides include alkyl glycoside, phenol glycoside, mustard glycoside and the like. Also, examples of the sugar alcohols include D,L-arabitol, ribitol, xylitol, D,L-sorbitol, D,L-mannitol, D,L-iditol, D,L-talitol, dulcitol allodulicitol and the like. In addition, maltitol obtained by hydrogenation of disaccharide and a reduced material (reduced starch syrup) obtained hydrogenation of oligosaccharide are suitably used. Particularly preferred non-reducing sugars among them are sugar alcohols and sucrose, and D-sorbitol, sucrose and reduced starch syrup are particularly desirable because they show the buffer action within an appropriate pH range and are low cost.

These non-reducing sugars can be used alone or as a mixture of two or more, and their ratio occupying the developing solution is preferably from 0.1 to 30% by weight, more preferably from 1 to 20% by weight.

Sufficient buffer action cannot be obtained at a ratio smaller than this range, and a ratio larger than this range poses a difficulty in carrying out high concentration and also causes a problem of increasing material cost. In this connection, when a reducing sugar is used in combination with abase, it causes a problem in that color of the solution changes periodically into brown, pH is also lowered gradually and thereby the developing property is reduced.

A conventionally well known alkali agent can be used as the base to be combined with the non-reducing sugar. For example, sodium hydroxide, potassium hydroxide, lithium hydroxide, sodium tertiary phosphate, potassium tertiary phosphate, ammonium tertiary phosphate, sodium secondary phosphate, potassium secondary phosphate, ammonium secondary phosphate, sodium carbonate, potassium carbonate, ammonium carbonate, sodium bicarbonate, potassium bicarbonate, ammonium bicarbonate, sodium borate, potassium borate, ammonium borate and the like inorganic alkali agents can be cited. Also useful are monomethylamine, dimethylamine, trimethylamine, monoethylamine, diethylamine, triethylamine, monoisopropylamine, diisopropylamine, triisopropylamine, n-butylamine, monoethanolamine, diethanolamine, triethanolamine, monoisopropanolamine, diisopropanolamine, ethyleneimine, ethylenediamine, pyridine and the like organic alkali agents.

These alkali agents may be used alone or as a mixture of two or more. Preferred among them are sodium hydroxide and potassium hydroxide because of the reason that the pH adjustment within more broad pH range becomes possible by controlling their amount to the non-reducing sugar. Sodium tertiary phosphate, potassium tertiary phosphate, sodium carbonate, potassium carbonate and the like are also preferable because of their own buffer actions.

These alkali agents are added to adjust the pH value of developing solution within the range of from 9.0 to 13.5, and though the adding amount is decided based on the desired pH and the kind and adding amount of the non-reducing sugar, more preferred pH range is from 10.0 to 13.2.

An alkaline buffer solution comprising a weak acid and a strong base other than saccharides can be used jointly with the developing solution. It is desirable that the weak acid to be used in such a buffer solution has a dissociation constant (pKa) of from 10.0 to 13.2.

Such a weak acid is selected from those described in IONISATION CONSTANTS OF ORGANIC ACIDS IN AQUEOUS SOLUTION published by Pergamon Press, and the like, and its examples include 2,2,3,3-tetrafluoropropanol-1 (pKa 12.74), trifluoroethanol (ditto 12.37), trichloroethanol (ditto 12.24) and the like alcohols, pyridine-2-aldehyde (ditto 12.68), pyridine-4-aldehyde (ditto 12.05) and the like aldehydes, salicylic acid (ditto 13.0), 3-hydroxy-2-naphthoic acid (ditto 12.84), catechol (ditto 12.6), gallic acid (ditto 12.4), sulfosalicylic acid (ditto 11.7), 3,4-dihydroxysulfonic acid (ditto 12.2), 3,4-dihydroxybenzoic acid (ditto 11.94), 1,2,4-trihydroxybenzene (ditto 11.82), hydroquinone (ditto 11.56), pyrogallol (ditto 11.34), o-cresol (ditto 10.33), resorcinol (ditto 11.27), p-cresol (ditto 10.27), m-cresol (ditto 10.09) and the like compounds having phenolic hydroxyl group,

2-butanoneoxime (ditto 12.45), acetoxime (ditto 12.42), 1,2-cycloheptanedionedioxime (ditto 12.3), 2-hydroxybenzaldehydeoxime (ditto 12.10), dimethylglyoxime (ditto 11.9), ethanediamidodioxime (ditto 11.37), acetophenoneoxime (ditto 11.35) and the like oximes, and adenosine (ditto 12.56), inosine (ditto 12.5), guanine (ditto 12.3), cytosine (ditto 12.2), hypoxanthine (ditto 12.1), xanthine (ditto 11.9) and the like nucleic acid-related substances, as well as diethylaminomethylphosphonic acid (ditto 12.32), 1-amino-3,3,3-trifluorobenzoic acid (ditto 12.29), isopropylidenediphosphonic acid (ditto 12.10), 1,1-ethylidenediphosphonic acid (ditto 11.54), 1-hydroxy 1,1-ethylidenediphosphonate (ditto 11.52), benzimidazole (ditto 12.86), thiobenzamide (ditto 12.8), picolinethioamide (ditto 12.55), barbituric acid (ditto 12.5) and the like weak acids.

Preferred among these weak acids are sulfosalicylic acid and salicylic acid. As the bases to be combined with these weak acids, sodium hydroxide, ammonium hydroxide, potassium hydroxide and lithium hydroxide are suitably used. These alkali agents are used alone or as a mixture of two or more. The aforementioned various alkali agents are used by adjusting the pH within a desirable range by their concentration and combination.

In order to improve acceleration of developing ability, dispersion of development residue and ink-philic property of image parts on printing plate, various surface active agents and organic solvents can be added to the developing solution as occasion demands. As desirable surface active agents, anionic, cationic, nonionic and ampholytic surface active agents can be cited.

Preferred examples of the surface active agents include polyoxyethylene alkyl ethers, polyoxyethylene alkyl phenyl ethers, polyoxyethylene polystyryl phenyl ethers, polyoxyethylene polyoxypropylene alkyl ethers, glycerol fatty acid partial esters, sorbitan fatty acid partial esters, pentaerythritol fatty acid partial esters, propylene glycol monofatty acid esters, sucrose fatty acid partial esters, polyoxyethylene sorbitan fatty acid partial esters, polyoxyethylene sorbitol fatty acid partial esters, polyethylene glycol fatty acid partial esters, polyglycerol fatty acid partial esters, polyoxyethylene-modified castor oils, polyoxyethylene glycerol fatty acid partial esters, fatty acid diethanolamides, N,N-bis-2-hydroxyalkylamines, polyoxyethylene alkylamine, triethanolamine fatty acid ester, trialkylamine oxide and the like nonionic surface active agents, fatty acid salts, abietic acid salts, hydroxyalkane sulfonic acid salts, alkane sulfonic acid salts, dialkyl sulfosuccinic acid ester salts, straight chain alkylbenzene sulfonic acid salts, branched chain alkylbenzene sulfonic acid salts, alkylnaphthalene sulfonic acid salts, alkyl phenoxypolyoxyethylenepropyl sulfonic acid salts, polyoxyethylene alkylsulfophenyl ether salts, N-methyl-N-oleyltaurine sodium salt, N-alkyl sulfosuccinate monoamide disodium salt, petroleum sulfonic acid salts, sulfated beef tallow oil, sulfuric acid ester salts of fatty acid alkyl ester, alkyl sulfuric acid ester salts, polyoxyethylene alkyl ether sulfuric acid ester salts, fatty acid monoglyceride sulfuric acid ester salts, polyoxyethylene alkylphenyl ether sulfuric acid ester salts, polyoxyethylene styrylphenyl ether sulfuric acid ester salts, alkyl phosphoric acid ester salts, polyoxyethylene alkyl ether phosphoric acid ester salts, polyoxyethylene alkylphenyl ether phosphoric acid ester salts, partial saponification products of styrene/maleic anhydride copolymer, partial saponification products of olefin/maleic anhydride copolymer, naphthalene sulfonate formalin condensation products and the like anionic surface active agents, alkylamine salts, tetrabutylammonium bromide and the like quaternary ammonium salts, polyoxyethylene alkylamine salts, polyethylene polyamine derivative and the like cationic surface active agents, and carboxybetaines, aminocarboxylic acids, sulfobetaines, aminosulfuric acid esters, imidazolines and the like ampholytic surface active agents. Among the surface active agents cited in the above, the term polyoxyethylene can be replaced by polyoxymethylene, polyoxypropylene, polyoxybutylene and the like polyoxyalkylene, and such surface active agents are also included.

Further preferable surface active agents are fluorine system surface active agents which contain perfluoroalkyl group in the molecules. Examples of such fluorine system surface active agents include perfluoroalkyl carbonic acid salt, perfluoroalkyl sulfonic acid salt, perfluoroalkyl phosphoric acid ester and the like anion types, perfluoroalkylbetaine and the like ampholytic types, perfluoroalkyl trimethylammonium salt and the like cation types and perfluoroalkylamine oxide, perfluoroalkylethylene oxide addition product, perfluoroalkyl group- and hydrophilic group-containing oligomer, perfluoroalkyl group- and lipophilic group-containing oligomer, perfluoroalkyl group-, hydrophilic group- and lipophilic group-containing oligomer, perfluoroalkyl group- and lipophilic group-containing urethane and the like nonionic types. The aforementioned surface active agents can be used alone or as a mixture of two or more, and are added to the developing solution within the range of from 0.001 to 10% by weight, more preferably from 0.01 to 5% by weight.

Various development stabilizing agents can be used in the developing solution. Their desirable examples include polyethylene glycol addition products of sugar alcohols, tetrabutylammonium hydroxide and the like tetraalkylammonium salts, tetrabutylphosphonium bromide and the like phosphonium salts and diphenyliodonium chloride and the like iodonium salts described in JP-A-6-282079. Also can be exemplified are the anionic surface active agents or ampholytic surface active agents described in JP-A-50-51324, the water-soluble cationic polymers described in JP-A-55-95946 and the water-soluble ampholytic polymer electrolytes described in JP-A-56-142528.

Further included are the organic boron compounds to which alkylene glycol is added as described in JP-A-59-84241, the polyoxyethylene-polyoxypropylene block polymer type water-soluble surface active agents described in JP-A-60-111246, the polyoxyethylene-polyoxypropylene-substituted alkylenediamine compounds described in JP-A-60-129750, the polyethylene glycol having a weight average molecular weight of 300 or more described in JP-A-61-215554, the fluorine-containing surface active agents having cationic groups described in JP-A-63-175858 and the water-soluble ethylene oxide addition compounds obtained by adding 4 mol or more of ethylene oxide to an acid or alcohol, and water-soluble polyalkylene compounds, described in JP-A-2-39157.

As occasion demands, an organic solvent is added to the developing solution. As such an organic solvent, a solvent having a solubility in water of about 10% by weight or less is desirable and preferably selected from those having 5% by weight or less. Its examples include 1-phenylethanol, 2-phenylethanol, 3-phenyl-1-propanol, 4-phenyl-1-butanol, 4-phenyl-2-butanol, 2-phenyl-1-butanol, 2-phenoxyethanol, 2-benzyloxyethanol, o-methoxybenzyl alcohol, m-methoxybenzyl alcohol, p-methoxybenzyl alcohol, benzyl alcohol, cyclohexanol, 2-methylcyclohexanol, 3-methylcyclohexanol, 4-methylcyclohexanol, N-phenylethanolamine, N-phenyldiethanolamine and the like.

The organic solvent content is from 0.1 to 5% by weight based on the total weight of the used solution. Since its using amount is closely related to the using amount of surface active agent, it is desirable to increase amount of the surface active agent as amount of the organic solvent increases. This is because the organic solvent is not completely dissolved when amount of the surface active agent is small and a large amount of the organic solvent is used so that security of good developing ability cannot be expected.

A reducing agent can further be added to the developing solution. This prevents staining of the printing plate. Examples of desirable organic reducing agent include thiosalicylic acid, hydroquinone, Metol, methoxyquinone, resorcin, 2-methylresorcin and the like phenol compounds and phenylenediamine, phenylhydrazine and the like amine compounds. In addition, examples of desirable inorganic reducing agent include sodium salt, potassium salt, ammonium salt and the like of sulfurous acid, sulfurous hydrogen acid, phosphorous acid, phosphorous hydrogen acid, phosphorous dihydrogen acid, thiosulfuric acid, dithionic acid and the like inorganic acids.

Particularly superior among these reducing agents are sulfites. These reducing agents are contained preferably within the range of from 0.05 to 5% by weight in the developing solution at the time of its use.

An organic carboxylic acid can also be added to the developing solution. Preferred organic carboxylic acids are an aliphatic carboxylic acid and an aromatic carboxylic acid having from 6 to 20 carbon atoms. Illustrative examples of the aliphatic carboxylic acid include capronic acid, enanthylic acid, caprylic acid, lauric acid, myristic acid, palmitic acid, stearic acid and the like, of which particularly preferred are alkane acids having from 8 to 12 carbon atoms. In addition, they may be unsaturated fatty acids having double bonds in the carbon chains or those of branched carbon chains. The aromatic carboxylic acid is a compound in which carboxyl group is substituted on benzene ring, naphthalene ring, anthracene ring or the like, and its illustrative examples include o-chlorobenzoic acid, o-chlorobenzoic acid, o-hydroxybenzoic acid, p-hydroxybenzoic acid, o-aminobenzoic acid, p-aminobenzoic acid, 2,4-dihydroxybenzoic acid, 2,5-dihydroxybenzoic acid, 2,6-dihydroxybenzoic acid, 2,3-dihydroxybenzoic acid, 3,5-dihydroxybenzoic acid, gallic acid, 1-hydroxy-2-naphthoic acid, 3-hydroxy-2-naphthoic acid, 2-hydroxy-1-naphthoicacid, 1-naphthoicacid, 2-naphthoicacid and the like, of which hydroxynaphthoic acid is particularly effective.

It is desirable to use the aforementioned aliphatic and aromatic carboxylic acids as sodium salts, potassium salts or ammonium salts in order to increase their solubility in water. Though the organic carboxylic acid content in the developing solution to be used in the invention is not particularly limited, the content of lower than 0.1% by weight does not bear sufficient effect, and the content of 10% by weight or more does not bear proportionally improved effect but may rather prevent dissolution of other additives when jointly used. Accordingly, the adding amount is preferably from 0.1 to 10% by weight, more preferably from 0.5 to 4% by weight, based on the developing solution at the tie of its use.

As occasion demands, an antiseptic, a coloring agent, a thickener, an antifoaming agent, a water softener and the like can be further contained in the developing solution. Examples of the water softener include polyphosphoric acid and its sodium salt, potassium salt and ammonium salt, ethylenediaminetetraacetic acid, diethylenetriaminepentaacetic acid, triethylenetetraminehexaacetic acid, hydroxyethylethylenediaminetriacetic acid, nitrilotriacetic acid, 1,2-diaminocyclohexanetetraacetic acid, 1,3-diamino-2-propanoltetraacetic acid and the like aminopolycarboxylic acids and their sodium salt, potassium salt and ammonium salt, aminotri(methylenephosphonic acid), ethylenediaminetetra(methylenephosphonic acid),diethylenetriaminepenta(methylenephosphonic acid), triethylenetetraminehexa(methylenephosphonic acid), hydroxyethylethylenediaminetri(methylenephosphonic acid) and 1-hydroxyethane-1,1-diphosphonic acid and their sodium salt, potassium salt and ammonium salt.

Optimum value of such a water softener changes depending on its chelation, hardness of hard water to be used and amount of the hard water, but its general using amount is within the range of from 0.01 to 5% by weight, more preferably from 0.01 to 0.5% by weight, based on the developing solution at the time of its use. Its adding amount smaller than this range cannot sufficiently achieve the desired object, and in case that the adding amount is larger than this range, decoloration and the like bud influences are exerted upon the image parts. The remaining component of the developing solution is water. It is advantageous from the transportation point of view to prepare the developing solution as a concentrated solution by reducing the water content prior to use and to dilute it with water at the time of its use. Appropriate degree of concentration in this case is such that each component is not separated and precipitated.

The developing solution described in JP-A-6-282079 can also be used as the developing solution of the lithographic printing plate of the invention. This is a developing solution which contains a silicic acid alkali metal salt having an SiO₂/M₂O (M represents an alkali metal) molar ratio of from 0.5 to 2.0 and a water-soluble ethylene oxide addition compound obtained by adding 5 moles or more of ethylene oxide to a sugar alcohol having 4 or more hydroxyl groups. The sugar alcohol is a polyhydric alcohol which corresponds to a saccharide whose aldehyde group and ketone group are reduced and thereby converted into the first and second alcohol groups respectively. Illustrative examples of the sugar alcohol include D,L-threitol, erythritol, D,L-arabitol, ribitol, xylitol, D,L-sorbitol, D,L-mannitol, D,L-iditol, D,L-talitol, dulcitol, allodulicitol and the like, and also included are di, tri, tetra, penta and hexaglycerols prepared by condensing corresponding sugar alcohol. The aforementioned water-soluble ethylene oxide addition compound is obtained by adding 5 moles or more of ethylene oxide to 1 mole of the aforementioned sugar alcohol. In addition, as occasion demands, the ethylene oxide addition compound may be subjected to block copolymerization with propylene oxide within such a range that the solubility can be maintained. These ethylene oxide addition compounds may be used alone or as a combination of two or more.

Adding amount of these water-soluble ethylene oxide addition compounds is preferably from 0.001 to 5% by weight, more preferably from 0.001 to 2% by weight, based on the developing solution (working solution).

In order to improve acceleration of developing ability, dispersion of development residue and ink-philic property of image parts on printing plate, the aforementioned various surface active agents and organic solvents can be added to this developing solution as occasion demands.

The photosensitive lithographic printing plate processed using a developing solution having such a composition is subjected to after treatment with washing water, a rising solution containing a surface active agent and the like and a finisher or protective gum solution containing gum arabic, starch derivatives and the like as the main components. These treatments can be used in various combinations for the after treatment of the photosensitive lithographic printing plate of the invention.

In recent years, in order to rationalize and standardize plate preparation works, an automatic developing machine for PS plate use is broadly used in the field of mold plate printing. This automatic developing machine generally comprises a developing part and an after treatment part, and comprises a PS plate transporting apparatus, respective processing solution vessels and a spraying apparatus, in which a PS plate after exposure is horizontally transported while carrying out development and after treatment by spraying each pumped up processing solution through a spray nozzle. Also known recently are a method in which the developing treatment is carried out by soaking a PS plate by transporting it into a processing liquid vessel filled with a processing liquid using a submerged guide roll or the like and a method in which a plate after development is washed with water by supplying a predetermined small amount of washing water to the plate surface and the waste water is recycled as a diluting water of the developing solution mother liquid.

In such an automatic treatment, the treatment can be carried out by supplementing each treating liquid with respective replenisher in response to the treating amount, operation time and the like. Also can be employed is a so-called disposable treatment system in which the treatment is carried out using a substantially unused treating liquid. The lithographic printing plate obtained by such a treatment is attached to an offset printing machine and used for the printing of a large number of sheets.

### EXAMPLES

The invention is further described based on examples. However, the invention is not restricted by these examples.

### Examples 1 to 5 and Comparative Example 1

[Preparation of Support]

The surface of a JIS A 1050 aluminum sheet was pebbled with a rotary nylon brush using a pamis-water suspension as the abrasive material. The surface roughness (center line average roughness) in this case was 0.5 μm. After washing with water, this was soaked in 10% sodium hydroxide aqueous solution heated to 70° C. to carry out etching such that dissolved amount of the aluminum became 6 g/m³. After washing with water, this was neutralized by soaking for 1 minute in 30% nitric acid aqueous solution and then thoroughly washed with water. Thereafter, 20 seconds of electrolytic roughening was carried out in 0.7% nitric acid aqueous solution using rectangular wave alternating waveform voltages of anode voltage of 13 V and cathode voltage of 6 V, and the surface was washed by soaking in 50° C. solution of 20% sulfuric acid and then washed with water.

A porous anode oxidation coat forming treatment of the aluminum sheet after surface roughening was carried out in 20% sulfuric acid aqueous solution using continuous current. By carrying out electrolysis at a current density of 5 A/dm⁵ and controlling the electrolysis time, a substrate having an anode oxidation coat of 4.0 g in weight/m² on the surface was prepared. A substrate (a) having a sealing ratio of 60% was prepared by treating this substrate for 10 seconds in a steam chamber saturated at 100° C. under 1 atmospheric pressure.

The substrate (a) was treated with 2.5% by weight aqueous solution of sodium silicate at 30° C. for 10 seconds to make its surface hydrophilic, the following undercoat solution was applied thereto and then the coating film was dried at 80° C. for 15 seconds to obtain a support [A] for lithographic printing plate use. Covering amount of the coat film after drying was 15 mg/m².

[Undercoat Solution]

The following copolymer having a molecular weight of 28,000

| | | |
|---|---|---|
| The following copolymer having a molecular weight of 28,000 | 0.3 | g |
| Methanol | 100 | g |
| Water | 1 | g |

| | |
|---|---|
| 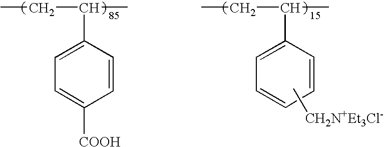 | molecular weight 28,000 |

[Formation of Recording Layer]

The following photosensitive solution 1 was coated on the thus obtained undercoated support [A] to a coating amount of 1.8 g/m² and dried to form a photosensitive layer (recording layer), thereby obtaining a lithographic printing plate precursor 1.

[Photosensitive Solution 1]

| | |
|---|---|
| Adding resin (described in Table 1) (resin (A)) | 0.03 g |
| Novolak resin (resin (B)) (m/p-cresol (6/4), weight average | 0.90 g |
| molecular weight 7,000, unreacted cresol 0.5% by weight) | |
| Ethyl methacrylate/isobutyl methacrylate/methacrylic acid | 0.10 g |
| (35/35/30 % by mol) copolymer | |
| Cyanine dye A (the following structure) | 0.1 g |
| Phthalic anhydride | 0.05 g |
| p-Toluenesulfonic acid | 0.002 g |
| Ethyl Violet in which its counter ion was converted into | 0.02 g |
| 6-hydxoxy-β-naphthalenesulfonic acid | |
| A fluorine system polymer (Defenser F-176 (solid contents | 0.015 g |
| 20%), mfd. by Dainippon Ink & Chemicals, Inc.) | |
| A fluorine system polymer (Defenser MCF-312 (solid | 0.035 g |
| contents 30%), mfd. by Dainippon Ink & Chemicals, Inc.) | |
| Methyl ethyl ketone | 12 g |

Cyanine Dye A:

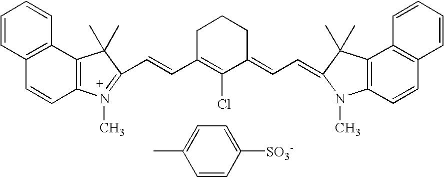

### Examples 6 to 10 and Comparative Example 2

The following photosensitive solution 2 was prepared. This photosensitive solution 2 was coated on the same support [A] used in Example 1 to a coating amount of 1.3 g/m² and dried to form a photosensitive layer, thereby obtaining a lithographic printing plate precursor 2.

[Photosensitive Solution 2]

| | |
|---|---|
| Adding resin (described in Table 2) (resin (A)) | 0.12 g |
| Copolymer 1 (to be described below in detail) | 0.75 g |
| Novolak resin (resin (B)) (weight average molecular weight | 0.25 g |
| 4,500, unreacted cresol 0.4% by weight) | |
| p-Toluenesulfonic acid | 0.003 g |
| Tetrahydrophthalic anhydride | 0.03 g |
| Cyanine dye A | 0.017 g |
| Victoria Pure Blue BOH in which its counter ion was | 0.015 g |
| converted into 1-naphthalenesulfonic acid anion | |
| 3-Methoxy-4-diazodiphenylamine hexafluorophosphate | 0.02 g |
| n-Dodecyl stearate | 0.03 g |
| A fluorine system polymer (Defenser F-176 (solid contents | |
| 20%), mfd. by Dainippon Ink & Chemicals, Inc.) | |
| cf. Table 4 | |
| A fluorine system polymer (Defenser MCF-312 (solid | |
| contents 30%), mfd. by Dainippon Ink & Chemicals, Inc.) | |
| cf. Table 4 | |
| γ-Butyllactone | 10 g |
| Methyl ethyl ketone | 10 g |
| 1-Methoxy-2-propanol | 8 g |

[Synthesis of copolymer 1]

A 31.0 g (0.36 mol) portion of methacrylic acid, 39.1 g (0.36 mol) of ethyl chloroformate and 200 ml of acetonitrile were put into a 500 ml capacity three neck flask equipped with a stirrer, a condenser tube and a dropping funnel, and the mixture was stirred while cooling in an ice water bath. To this mixture was added dropwise 36.4 g (0.36 mol) of triethylamine through the dropping funnel spending about 1 hour. After completion of the dropwise addition, the ice water bath was removed and the mixture was stirred at room temperature for 30 minutes.

A 51.7 g (0.30 mol) portion of p-aminobenzenesulfonamide was added to this reaction mixture, and the resulting mixture was stirred for 1 hour while incubating at 70° C. in an oil bath. After completion of the reaction, this mixture was put into 1 liter of water while stirring this water, and the thus obtained mixture was stirred for 30 minutes. This mixture was filtered to collect the precipitate which was made into slurry with 500 ml of water, and then this slurry was filtered and the thus obtained solid was dried, thereby obtaining white solid of N-(p-aminosulfonylphenyl)methacrylamide (yield 46.9 g).

Next, 4.61 g (0.0192 mol) of N-(p-aminosulfonylphenyl)methacrylamide, 2.58 g (0.0258 mol) of ethyl methacrylate, 0.80 g (0.015 mol) of acrylonitrile and 20 g of N,N-dimethylacetamide were put into a 20 ml capacity three neck flask equipped with a stirrer, a condenser tube and a dropping funnel, and the mixture was stirred while heating at 65° C. in a hot water bath. A 0.15 g portion of “V-65” (mfd. by Wako Pure Chemical Industries) was added to this mixture, and the resulting mixture was stirred for 2 hours in a stream of nitrogen while keeping at 65° C. A mixture of 4.61 g of N-(p-aminosulfonylphenyl)methacrylamide, 2.58 g of ethyl methacrylate, 0.80 g of acrylonitrile, N,N-dimethylacetamide and 0.15 g of “V-65” was further added dropwise to this reaction mixture through the dropping funnel spending 2 hours. After completion of the dropwise addition, the thus obtained mixture was stirred at 65° C. for 2 hours. After completion of the reaction, the mixture was mixed with 40 g of methanol and cooled, the resulting mixture was put into 2 liters of water while stirring this water, the mixture was stirred for 30 minutes, and then the precipitate was collected by filtration and dried to obtain 15 g of a white solid.

Weight average molecular weight (polystyrene standard) of this specific copolymer 1 was 53,000 when measured by a gel permeation chromatography.

### Examples 11 to 16 and Comparative Example 3

The following photosensitive solution 3A was coated on the same support [A] used in Example 1 and dried at 100° C. for 2 minutes to obtain a layer (A). The coating amount after drying was 1.04 g/m².

Thereafter the following photosensitive solution 3B was coated thereon and dried at 100° C. for 2 minutes to obtain a layer (B) (upper layer), thereby obtaining a lithographic printing plate precursor 3. The total coating amount of the photosensitive solutions after drying was 1.2 g/m².

[Photosensitive Solution 3A]

| | |
|---|---|
| Copolymer 1 | 0.75 g |
| Cyanine dye A | 0.04 g |
| p-Toluenesulfonic acid | 0.002 g |
| Tetrahydrophthalic anhydride | 0.05 g |
| A dye prepared by converting counter anion of Victoria Pure | 0.015 g |
| Blue BOH into 1-naphthalenesulfonic acid anion | |
| A fluorine system polymer C (Defenser F-176 (solid contents | |
| 20%), mfd. by Dainippon Ink & Chemicals, Inc.) | |
| cf. Table 4 | |
| γ-Butyllactone | 8 g |
| Methyl ethyl ketone | 7 g |
| 1-Methoxy-2-propanol | 7 g |
| [Photosensitive solution 3B] | |
| Adding resin (described in Table 3) (resin (A)) | 0.015 g |
| Novolak resin (resin (B)) (weight average molecular weight | 0.25 g |
| 4,500, unreacted cresol 0.5% by weight) | |
| Cyanine dye A | 0.05 g |
| n-Dodecyl stearate | 0.02 g |
| A fluorine system polymer (Defenser F-176 (solid contents | |
| 20%), mfd. by Dainippon Ink & Chemicals, Inc.) | |
| cf. Table 4 | |
| A fluorine system polymer (Defenser MCF-312 (solid | |
| contents 30%), mfd. by Dainippon Ink & Chemicals, Inc.) | |
| cf. Table 4 | |
| Methyl ethyl ketone | 7 g |
| 1-Methoxy-2-propanol | 7 g |

[Evaluation of Developing Latitude]

A test pattern was written in an image shape on the thus obtained photosensitive lithographic printing plate precursors 1 to 5 of the invention and the printing plate of Comparative Example 1, using Trendsetter manufactured by Creo at a beam strength of 9 W and a drum revolution speed of 150 rpm.

Firstly, each of the lithographic printing plate precursors exposed under the above conditions was developed for a developing time of 25 seconds using PS Processor 900H manufactured by Fuji Photo Film charged with the following alkali developing solution A, while keeping the liquid temperature at 28° C. At this stage, the presence or absence of staining and coloring caused by poorly developed recording layer residues was verified. Thereafter, the treatment was repeated by diluting with water, and conductivity of the developing solution after development was measured. The results are shown in the following Table 1. A result having large deference between the upper limit value and the lower limit value is evaluated as excellent.

[Evaluation Method of Image Density]

In printing each lithographic printing plate obtained by developing at around the central part conductivity of the developing latitude by Rislon printer manufactured by Komori Corporation using DIC-GEOS(N) Japanese ink (mfd. by Dainippon Ink & Chemicals, Inc.) as the ink, the printing was started in such a manner that the ink roller and printing paper were supplied after contacting a soaking roller to the plate surface and rolling it ten times, and the number of sheets of the printing paper required for correctly reproducing the image on the printing paper was counted to evaluate the image density.

<Composition of alkali developing solution A>

| | |
|---|---|
| SiO₂—K₂O (K₂O/SiO₂ = 1/1 (molar ratio)) | 4.0% by weight |
| Citric acid | 0.5% by weight |
| Polyethylene glycol modified sorbitol (average 30 | 1.0% by weight |
| units addition product) | |
| Water | 50.0% by weight |

TABLE 1

| | | | Developing | | | |
|---|---|---|---|---|---|---|
| | Resin | | latitude | | | Image |
| | | M. | Upper | Lower | | Density |
| Example | Composition | weight | limit | limit | Δ | (sheets) |
| 1 | i-propylphenol/ | Mw 2000 | 84 | 73 | 11 | 5 |
| | formaldehyde | | | | | |
| | condensation | | | | | |
| | resin | | | | | |
| 2 | t-butylphenol/ | Mw 3500 | 85 | 72 | 13 | 6 |
| | formaldehyde | | | | | |
| | condensation | | | | | |
| | resin | | | | | |
| 3 | t-amylphenol/ | Mw 2500 | 84 | 72 | 12 | 5 |
| | formaldehyde | | | | | |
| | condensation | | | | | |
| | resin | | | | | |
| 4 | hexylphenol/ | Mw 2300 | 84 | 72 | 12 | 5 |
| | formaldehyde | | | | | |
| | condensation | | | | | |
| | resin | | | | | |
| 5 | i-propylcresol/ | Mw 1800 | 83 | 72 | 11 | 5 |
| | formaldehyde | | | | | |
| | condensation | | | | | |
| | resin | | | | | |
| Comp. 1 | none | | 75 | 72 | 3 | 18 |

From the results of Table 1, the photosensitive lithographic printing plate precursors of the invention were able to realize superior ink density and developing latitude.

In addition, the photosensitive lithographic printing plates 6 to 15 of the invention and the printing plates of Comparative Examples 2 and 3 were treated by charging an alkali developing solution B into the aforementioned PS Processor 900H and diluting with water in the aforementioned manner at a liquid temperature of 28° C. for a developing period of 14 seconds, and the developing latitude was evaluated in the same manner.

<Composition of alkali developing solution B>

| | |
|---|---|
| D-Sorbitol | 2.5% by weight |
| Sodium hydroxide | 0.85% by weight |
| Diethylenetriaminepenta(methylenesulfonic acid) | 0.05% by weight |
| 5Na salt | |
| Water | 50.0% by weight |

TABLE 2

| | | | Developing | | | |
|---|---|---|---|---|---|---|
| | Resin | | latitude | | | Image |
| | | M. | Upper | Lower | | Density |
| Example | Composition | weight | limit | limit | Δ | (sheets) |
| 6 | i-propylphenol/ | Mw 2000 | 52 | 40 | 12 | 5 |
| | formaldehyde | | | | | |
| | condensation | | | | | |
| | resin | | | | | |
| 7 | t-butylphenol/ | Mw 3500 | 51 | 38 | 13 | 6 |
| | formaldehyde | | | | | |
| | condensation | | | | | |
| | resin | | | | | |
| 8 | t-amylphenol/ | Mw 2500 | 54 | 41 | 13 | 6 |
| | formaldehyde | | | | | |
| | condensation | | | | | |
| | resin | | | | | |
| 9 | hexylphenol/ | Mw 2300 | 53 | 41 | 12 | 5 |
| | formaldehyde | | | | | |
| | condensation | | | | | |
| | resin | | | | | |
| 10 | i-propylcresol/ | Mw 1800 | 52 | 41 | 11 | 6 |
| | formaldehyde | | | | | |
| | condensation | | | | | |
| | resin | | | | | |
| Comp. 2 | none | — | 47 | 40 | 7 | 28 |

TABLE 3

| | | | Developing | | | |
|---|---|---|---|---|---|---|
| | Resin | | latitude | | | Image |
| | | M. | Upper | Lower | | Density |
| Example | Composition | weight | limit | limit | Δ | (sheets) |
| 11 | i-propylphenol/ | Mw 2000 | 52 | 40 | 12 | 6 |
| | formaldehyde | | | | | |
| | condensation | | | | | |
| | resin | | | | | |
| 12 | t-butylphenol/ | Mw 3500 | 51 | 38 | 13 | 5 |
| | formaldehyde | | | | | |
| | condensation | | | | | |
| | resin | | | | | |
| 13 | t-amylphenol/ | Mw 2500 | 54 | 42 | 12 | 5 |
| | formaldehyde | | | | | |
| | condensation | | | | | |
| | resin | | | | | |
| 14 | hexylphenol/ | Mw 2300 | 52 | 40 | 12 | 6 |
| | formaldehyde | | | | | |
| | condensation | | | | | |
| | resin | | | | | |
| 15 | i-propylcresol/ | Mw 1800 | 50 | 37 | 13 | 6 |
| | formaldehyde | | | | | |
| | condensation | | | | | |
| | resin | | | | | |
| Comp. 3 | none | — | 47 | 40 | 7 | 25 |

From the results of Tables 2 and 3, the photosensitive lithographic printing plate of the invention were able to realize superior ink density and developing latitude.

According to the photosensitive lithographic printing plate of the invention, ink acceptability (image density) and developing latitude can be improved by containing a resin of a specified structure in the photosensitive layer.

This application is based on Japanese Patent application JP 2002-119260, filed Apr. 22, 2002, the entire content of which is hereby incorporated by reference, the same as if set forth at length.

What is claimed is:

1. A photosensitive lithographic printing plate which comprises a photosensitive layer comprising:
(A) a resin prepared by condensing substituted phenols represented by the following formula (I) with aldehydes;
(B) a resin prepared by condensing phenols selected from cresol, phenol and xylenol with aldehydes; and
(C) a light-heat converting substance: 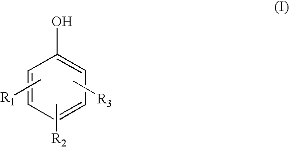
wherein R₁ and R₂ each represents a hydrogen atom, an alkyl group or a halogen atom, and R₃ represents an alkyl group having from 3 to 6 carbon atoms or cycloalkyl group having from 3 to 6 carbon atoms.

2. The photosensitive lithographic printing plate according to claim 1, wherein the aldehydes of the resin (A) are at least one of formaldehyde, acetaldehyde, acrolein and crotonaldehyde.

3. The photosensitive lithographic printing plate according to claim 1, wherein the aldehydes of the resin (A) are at least one of formaldehyde and acetaldehyde.

4. The photosensitive lithographic printing plate according to claim 1, wherein the aldehydes of the resin (B) are at least one of formaldehyde, acetaldehyde, acrolein and crotonaldehyde.

5. The photosensitive lithographic printing plate according to claim 1, wherein the aldehydes of the resin (B) are at least one of formaldehyde and acetaldehyde.

6. The photosensitive lithographic printing plate according to claim 1, wherein the resin (A) has a weight average molecular weight of from 500 to 50,000.

7. The photosensitive lithographic printing plate according to claim 1, wherein the resin (B) has a weight average molecular weight of from 1,000 to 700,000.

8. The photosensitive lithographic printing plate according to claim 1, wherein the resin (B) has a number average molecular weight of from 750 to 650,000.

9. The photosensitive lithographic printing plate according to claim 1, wherein a ratio of the resin (A) to total solid contents in the photosensitive layer is from 0.1% by weight to 20% by weight

10. The photosensitive lithographic printing plate according to claim 1, which further comprises an alkali-soluble resin.
